(19) United States
(12) Patent Application Publication
(10) Pub. No.: US 2013/0031436 A1
(43) Pub. Date: Jan. 31, 2013

(54) SEMICONDUCTOR INTEGRATED CIRCUIT, SCAN FLIP-FLOP, AND TEST METHOD OF SEMICONDUCTOR INTEGRATED CIRCUIT

(71) Applicant: Kenichi MIZUTANI, Kanagawa (JP)

(72) Inventor: Kenichi MIZUTANI, Kanagawa (JP)

(73) Assignee: Renesas Electronics Corporation

(21) Appl. No.: 13/545,616

(22) Filed: Jul. 10, 2012

(30) Foreign Application Priority Data
Jul. 25, 2011 (JP) 2011-161663

(51) Int. Cl. G01R 31/3177; G06F 11/25

(52) U.S. Cl. 714/729; 714/E11.155

(57) ABSTRACT

A semiconductor integrated circuit according to an aspect of the invention includes scan flip-flops and a scan control unit. The scan flip-flop outputs backup data that is held as an internal state under control of the scan control unit, and the scan flip-flop holds backup data output from the scan flip-flop in the scan flip-flop under control of the scan control unit.

### CROSS-REFERENCE TO RELATED APPLICATIONS

This application is based upon and claims the benefit of priority from Japanese patent application No. 2011-161663, filed on Jul. 25, 2011, the disclosure of which is incorporated herein in its entirety reference.

### BACKGROUND

The present invention relates to a semiconductor integrated circuit, a scan flip-flop, and a test method of a semiconductor integrated circuit. In particular, the present invention relates to a semiconductor integrated circuit that outputs the internal states of flip-flops as backup data, a scan flip-flop, and a test method.

In recent years, the number of systems that perform various safety controls by using semiconductor integrated circuits, such as automobiles, is increasing. In such systems, in order to verify the safety, it is necessary to carry out a fault diagnosis of the circuit not only when the product is shipped but also when the system is in operation after the shipment. Therefore, diagnosis circuits that are used to carry out a fault diagnosis of internal circuits are incorporated in semiconductor integrated circuits.

In general, a semiconductor integrated circuit operates while maintaining its internal state. Therefore, if a fault diagnosis is carried out by using a fault circuit when the system is in operation, this internal state is changed. The internal state includes parameters necessary for the system operation. Therefore, if the internal state is disrupted, the system operation is significantly affected. Accordingly, it is strongly desired to develop a fault diagnosis method that does not disrupt the pre-diagnosis internal state during the fault diagnosis.

Japanese Unexamined Patent Application Publication No. 2006-300650, for example, discloses a semiconductor integrated circuit in which a fault diagnosis is carried out when the system is in operation. In Japanese Unexamined Patent Application Publication No. 2006-300650, the semiconductor integrated circuit has a function of restoring the internal state to the pre-diagnosis internal state after a fault diagnosis.

FIG. 10 is a configuration diagram showing a configuration of a related-art semiconductor integrated circuit disclosed in Japanese Unexamined Patent Application Publication No. 2006-300650. This related-art semiconductor integrated circuit Includes a logic circuit 1, a diagnosis circuit 2 that performs a fault diagnosis of the logic circuit 1, a register 3, which is a storage circuit that holds the internal state of the logic circuit 1, a restoration circuit 4 that supplies the internal state held by the register 3 to the logic circuit 1, and so on.

Further, the semiconductor integrated circuit includes a response circuit 5 that outputs a diagnosis start signal indicating the start of a diagnosis to the logic circuit 1 based on an input signal to the logic circuit land also outputs a restoration request signal indicating a transition from a diagnosis operation to a normal operation, to the restoration circuit 4.

The related-art semiconductor integrated circuit includes the diagnosis circuit 2 that can perform a fault diagnosis even when the semiconductor integrated circuit is in operation. Therefore, even when other circuits access the semiconductor integrated circuit during a diagnosis of the semiconductor integrated circuit, the semiconductor integrated circuit can continue the diagnosis while responding to the access. Alternatively, the semiconductor integrated circuit can interrupt the diagnosis operation in an appropriate manner and thereby return to the pre-diagnosis state. The semiconductor integrated circuit can perform a fault diagnosis while the semiconductor integrated circuit is in operation by storing the internal state of the logic circuit before the fault diagnosis and restoring the stored internal state into the logic circuit after the fault diagnosis.

FIG. 11 shows a configuration of a related-art scan flip-flop (scan register) included in the logic circuit 1 of the related-art semiconductor integrated circuit. This related-art scan flip-flop 6 is composed of a selector 7 and a flip-flop 8. The selector 7 selects either logic data supplied from other logic circuits or scan-in data according to a select signal SET and outputs the selected data to the flip-flop The flip-flop 8 holds and outputs the data supplied from the selector 7 according to a clock CLK.

In the related-art semiconductor integrated circuit, data held by the related-art scan flip-flop 6 is saved into the register 3 before a scan test for the logic circuit 1 starts. Then, scan-in data is input to the related-art scan flip-flop 6 and the scan test carried out. After the scan test has finished, the restoration circuit 4 restores the data stored in the register 3 into the related-art scan flip-flop 6.

### SUMMARY

As described above, the semiconductor integrated circuit disclosed in Japanese Unexamined Patent Application Publication No. 2006-300650 requires a new register that stores the internal state of a logic circuit, which is the data of the scan flip-flop, and a new restoration circuit that restores the stored internal state into the logic circuit in order to enable a fault diagnosis to be carried out while the semiconductor integrated circuit is in operation. Note that these new register and new restoration are separate circuits from the logic circuit. In recent years, as logic circuits have became larger in scale, the registers and the restoration circuits that are used to store and restore the internal states of the logic circuits have become also larger in circuit scale.

Therefore, there is a problem in the related-art semiconductor integrated circuit that, ire order to save and restore the internal state and thereby to carry out a fault diagnosis while the semiconductor integrated circuit is in operation, the circuit scale becomes larger.

A first aspect of the present invention is a semiconductor integrated circuit including: first and second scan flip-fl p that perform either a normal flip-flop operation through an internal flip-flop or a scan test operation through the internal flip-flop; and a scan control unit that controls the scan test operation performed. by the first and second flip-flops, wherein the first scan flip-flop includes a backup output unit that outputs backup data under control of the scan control unit, the backup data being held by a first flip-flop located in the first scan flip-flop as an internal state, and the second scan flip-flop includes a backup input unit that stores backup data output from the first scan flip-flop into second flip-flop located in the second scan flip-flop under control of the scan control unit.

Another aspect of the present invention is a scan flip-flop including: a master latch that holds and outputs input data; and a slave latch that holds and outputs data output by the master latch, wherein the scan flip-flop further includes: a first selector circuit that outputs either master data held by the master latch or slave data held by the slave latch as backup data; and a second selector circuit that supplies one of input logic data input from an external logic circuit, scan shift data to be scan-shifted, and the backup data output another scan flip-flop to the master latch.

Another aspect of the present invention is a test method a semiconductor integrated circuit including first and second scan flip-flops that perform either a normal flip-flop operation through an internal flip-flop or a scan test operation through the internal flip-flop, wherein the first scan flip-flop outputs backup data, the backup data being held by a first flip-flop located in the first scan flip-flop as an internal state, and the second scan stores backup data output from the first scan flip-flop into a second flip-flop located in the second scan flip-flop.

According to an aspect the present invention, since the first scan flip-flop outputs an internal state as backup data and the second scan flip-flop holds backup data the first scan flip-flop, there is no need to provide the semiconductor integrated circuit with the new register and the new restoration circuit in contrast to the related-art semiconductor integrated circuit, thus preventing the semiconductor integrated circuit from being increased in circuit scale.

According to an aspect of the present invention, it is possible to provide a semiconductor integrated circuit, flip-flop, and a test method of a semiconductor integrated circuit, capable of saving and restoring an internal state and thereby performing a fault diagnosis while the semiconductor integrated circuit is in operation, and capable of preventing the semiconductor integrated circuit from being increased in circuit scale.

### BRIEF DESCRIPTION OF THE DRAWINGS

The above and other aspects, advantages and features will be more apparent from the following description of certain embodiments taken in conjunction with the accompanying drawings, in which:

FIG. 1 is a schematic configuration diagram of a semiconductor integrated circuit according to first embodiment of the present invention;

FIG. 2 is a truth table of a scan control unit in a semiconductor integrated circuit according to first embodiment of the present invention;

FIG. 3 is a circuit configuration diagram of a scan flip-flop according to first embodiment of the present invention;

FIG. 4 is a truth table of a scan flip-flop according to first embodiment of the present invention;

FIG. 5 is a flowchart showing a test method of a semiconductor integrated circuit according to first embodiment of the present invention;

FIG. 6 is a timing chart showing a test method of a semiconductor integrated circuit according to first embodiment of the present invention;

FIG. 7 is a schematic configuration diagram of a semiconductor integrated circuit according to second embodiment of the present invention;

FIG. 8 is a circuit configuration diagram of a scan flip-flop according to second embodiment of the present invention;

FIG. 9 is a flowchart showing a test method of a semiconductor integrated circuit according to second embodiment of the present invention;

FIG. 10 is a configuration diagram showing a configuration of a semiconductor integrated circuit in related art; and

FIG. 11 is a circuit configuration diagram showing configuration of a scan flip-flop in related art.

### DETAILED DESCRIPTION

### First Embodiment

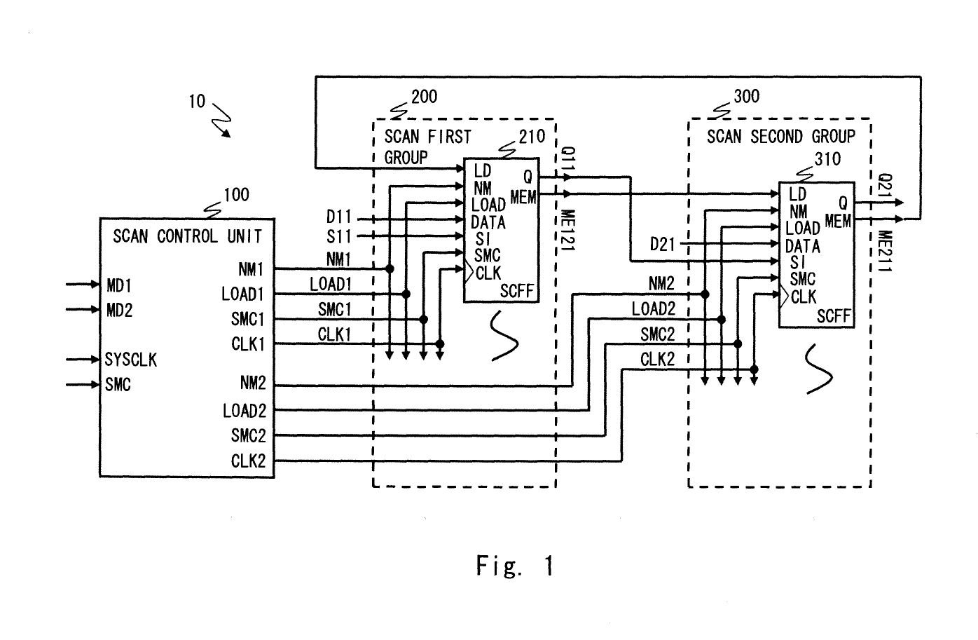

A first embodiment according to the present invention is explained hereinafter with reference to the drawings. Firstly, a configuration of a semiconductor integrated circuit according to a first embodiment of the present invention is explained with reference to FIGS. 1 to 4.

FIG. 1 is a schematic configuration diagram of a semiconductor integrated circuit according to first embodiment of the present invention. As shown FIG. 1, this semiconductor integrated circuit 10 includes a scan control unit 100, a scan first group 200, and a scan second group 300.

The semiconductor integrated circuit 10 is a one-chip semiconductor integrated circuit including a plurality of logic circuits (not shown). The semiconductor integrated circuit 10 performs a test (fault diagnosis) for an internal logic circuit(s) while the semiconductor integrated circuit 10 is in operation. That is, the semiconductor integrated circuit 10 operates according to an operating mode, and the semiconductor integrated circuit 10 has, as the operating mode, an actual operating mode in which the semiconductor integrated circuit 10 performs an ordinary operation and a test mode in which the semiconductor integrated circuit 10 performs a scan test. Further, the test mode includes a scan first group scan test mode in which the semiconductor integrated circuit 10 performs a scan test for the scan first group 200 and a scan second group scan test mode in which the semiconductor integrated circuit 10 performs a scan test for the scan second group 300.

The scan first group 200 includes at least one scan flip-flop (hereinafter referred to as “SCFF”) 210 as a scan flip-flop. Further, the scan second group 300 includes the same number of SCFF((s) 310 as the number of SCFF(s) included in the scan first group 200. Each of these scan groups is a group for which a scan test including a plurality of SCFFs is performed. Further, a scan test is performed for each scan group.

Each of the SCFFs 210 of the scan first group 200 corresponds to a respective one of the SCFFs 310 of the scan second group 300. When a scan test is performed for the SCFFs 210, the internal states of the SCFFs 210 are backed up in the SCFFs 310, whereas when a scan test is performed for the SCFFs 310, the internal states of the SCFFs 310 are backed up in the SCFFs 210. Note that for a pair of an SCFF 210 and an SCFF 310, one of the SCFFs may be called “one SCFF” and the other SCFF may be led “other SCFF”. In this embodiment, the only requirement for the scan first group 200 and the scan second group 300 is that they should include the same number of SCFFs as each other. Therefore, the SCFFs 210 included in the scan first group 200 do not need to have any relation with each other. Further, the SCFFs 310 included in the scan second group 300 also do not need to have any relation with each other. That is, the only requirement is that when one scan group is tested, the other scan group should be able to back up the internal state of the one scan group during the test.

The scan control unit 100 controls a test operation of the scan first group 200 and the scan second group 300 according to an input mode signal(s). Mode signals MD1 and MD2 for setting the operating mode of the scan groups, a system clock SYSCLK for supplying a necessary operating clock for a scan test, and a scan control signal SMC for controlling the scan test mode of SCFFs are input to the scan control unit 100. For example, the semiconductor integrated circuit 10 is equipped with external terminals and the mode signals MD1 and MD2, the system clock SYSCLK, and the scan control sign SMC are input from an external test device to the semiconductor integrated circuit 10 through the external terminals. Note that the system clock SYSCLK may be supplied from a clock generation circuit provided inside the semiconductor integrated circuit 10.

Specifically, the mode signals MD1 and MD2 are input through an MD1-terminal and an MD2-terminal of the scan control unit 100 and the system clock SYSCLK is input through an SYSCLK-terminal of the scan control unit 100. Further, the scan control signal SMC is input through an SMC-terminal of the scan control unit 100.

Further, the scan control unit 100 outputs a backup data select signal NM for controlling inputting/outputting of backup data, which is the internal state of an SCFF, a scan control signal SMC, a load signal LOAD for controlling a hold operation (hold state) of the SCFFs, and a clock CLK for supplying an operating clock to the SCFFs to each of the SCFFs of the scan first group 200 and the scan second group 300. As explained later, in order to perform a test for the scan first group 200 or the scan second group 300, the scan control unit 100 selects the scan first group 200 or the scan second group 300 according to the input mode signals MD1 and MD2 and generates a backup data select data NM and a load signal LOAD to be output to the SCFFs. Further, the scan control unit 100 generates a clock CLK to be output to the SCFFs based on the input system clock SYSCLK and also generates a scan control signal SMC to be output to the SCFFs based on the input scan control signal SMC.

Specifically, a scan first group backup data select signal NM1 for the scan first group is output from an NM1-terminal of the scan control unit 100 and input to NM-terminals of the SCFFs 210. A scan first group load signal LOAD1 for the scan first group is output from a LOAD1-terminal of the scan control unit 100 and input to LOAD-terminals of the SCFFs 210. A scan first group scan control signal SMC1 for the scan first group is output from an SMC1-terminal of the scan control unit 100 and input to SMC-terminals of the SCFFs 210. A scan first group clock CLK1 for the scan first group is output from a CLK1-terminal of the scan control unit 100 and input to CLK-terminals of the SCFFs 210.

Similarly, a scan second group backup data select signal NM2 for the scan second group is output from an NM2-terminal of the scan control unit 100 and input to NM-terminals of the SCFFs 310. A scan second group load signal LOAD2 for the scan second group is output from a LOAD2-terminal of the scan control unit 100 and input to LOAD-terminals of the SCFFs 310. A scan second group scan control signal SMC2 for the scan second group is output from an SMC2-terminal of the scan control unit 100 and input to SMC-terminals of the SCFFs 310. A scan second group clock CLK2 for the scan second group is output from a CLK2-terminal of the scan control unit 100 and input to CLK-terminals of the SCFFs 310.

Further, logic data DATA from other logic circuits and scan shift data SI used in a scan test are input to each SCFF of the scan first group 200 and the scan second group 300. Further, each SCFF of the scan first group 200 and the scan second group 300 outputs logic data Q, which is output data of the SCFF, and backup data MEM for baking up the internal state. For example, the logic data DATA is input from a logic circuit inside or outside the semiconductor integrated circuit 10, and the scan shift data SI is supplied from a test device outside the semiconductor integrated circuit 10 or input from the other SCFF.

Specifically, logic data D11 for the scan first group is externally input to a DATA-terminal of the SCFF 210. Scan shift data S11 for the scan first group is externally input to an SI-terminal of the SCFF 210. Logic data Q11 output by the scan first group is input from a Q-terminal of the SCFF 210 to an SI-terminal o e SCFF 310. Backup data ME121 output by the scan first group is input from an MEM-terminal of the SCFF 210 LD-terminal the SCFF 310.

Similarly, logic data D21 for the scan second group externally input to a DATA-terminal of the SCFF 310. Logic data Q21 output the scan second group is externally output from a Q-terminal of the SCFF 310. Backup data ME211 output by the scan second group is input from an MEM-terminal of the SCFF 310 to an LID-terminal of the SCFF 210. For example, the logic data Q21 is output to a test device through an external terminal of the semiconductor integrated circuit 10, and the test device performs a fault diagnosis of a logic circuit by using this data.

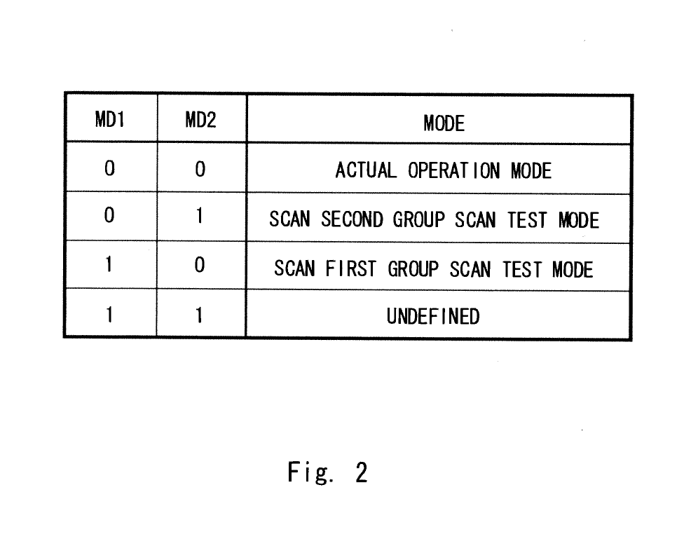

FIG. 2 is an operation truth table showing a relation between the input mode signals MD1 and MD2 and operating modes in the scan control unit 100 according to the first embodiment of the present invention.

When mode signals MD1=0 and MD2=0 are input to the scan control unit 100, the semiconductor integrated circuit 10 enters an actual operating mode. In this case, the scan control unit 100 performs control so that the SCFFs 210 of the scan first group 200 and the SCFFs 310 of the scan second group 300 perform a normal operation.

When mode signals MD1=0 and MD2=1 are input to the scan control unit 100, the semiconductor integrated circuit 10 enters a scan second group scan test mode. In this case, the scan control unit 100 performs control so that the SCFFs 310 of the scan second group 300 perform a scan test. Further, the internal state of the SCFFs 310 of the scan second group 300 is backed up (saved) in the SCFFs of the scan first group 200 before the scan test. Then, after the scan test, the internal state backed up in the SCFFs 210 of scan first group 200 restored (returned) into the SCFFs 310 of the scan second group 300. Further, the scan control unit 100 performs control so that the SCFFs 210 of the scan first group 200 perform a “through-pass” operation. As explained later, the term “through-pass” means such an operation that input data is not passed through the flip-flops in the SCFFs but is directly output by bypassing the flip-flops. By the through-pass, it is possible to prevent data stored in the flip-flops in the SCFFs from being destroyed. Further, is also possible to perform a fault diagnosis of signal lines connected between the SCFFs.

When mode signals MD1=1 and MD2=0 are input to the scan control unit 100, the semiconductor integrated circuit 10 enters a scan first group scan test mode. In this case, the scan control unit 100 performs control so that the SCFFs 210 of the scan firs group 200 perform a scan test. Further, the internal state of the SCFFs 210 of the scan first group 200 s backed up in the SCFFs 310 of the scan second group 300 before the scan test. Then r the scan test, the internal state backed up in the SCFFs 310 of the scan second group 300 is restored into the SCFFs 210 of the scan first group 200. Further, the scan control unit 100 performs control so that the SCFFs 310 of the scan second group 300 perform through-pass operation.

Note that the operating mode that the semiconductor integrated circuit 10 enters when mode signals MD1=1 and MD2=1 are input to the scan control unit 100 is not defined. In this case, the SCFFs may be controlled in an arbitrary manner. For example, the semiconductor integrated circuit 10 may perform a scan test without backing up the internal state.

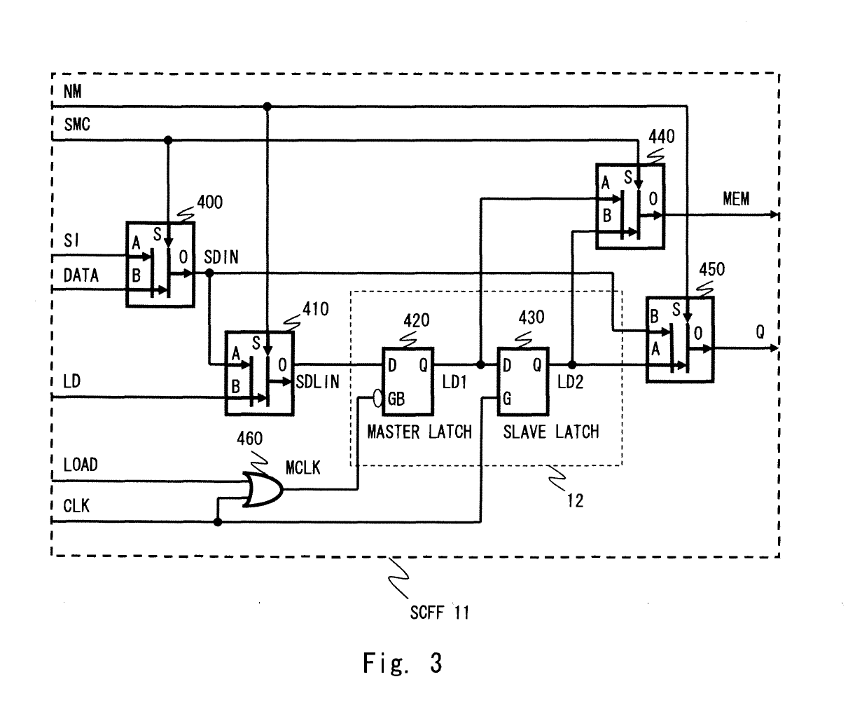

FIG. 3 shows a circuit configuration (macro configuration) of an SCFF according to the first embodiment of the present invention. This SCFF 11 corresponds to an SCFF 210 of the scan first group 200 and to an SCFF 310 of the scan second group 300.

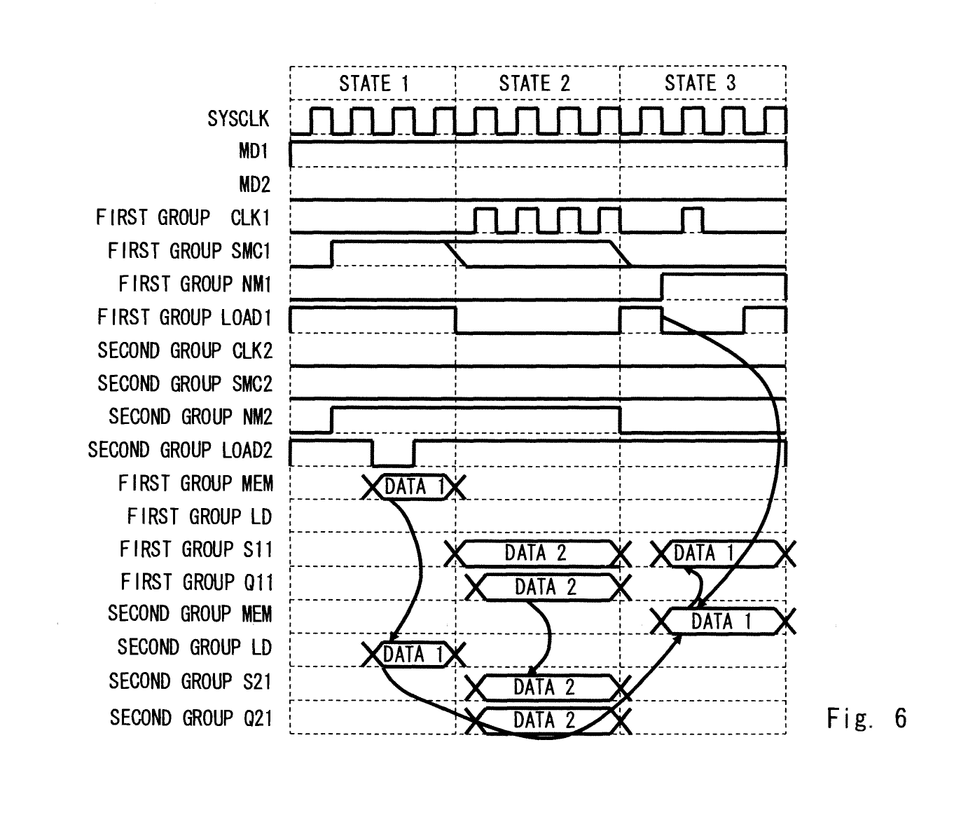

As shown in FIG. 3, the SCFF 11 includes selectors 400, 410, 440 and 450, a master latch 420, a slave latch 430, and a logical OR 460. Further, the master latch 420 and the slave latch 430 form a flip-flop 12. In comparison with the related-art SCFF shown in FIG. 6, the selector 400 and the flip-flop 12 shown in FIG. 3 have similar configurations with those of the selector 7 and the flip-flop 8 shown in FIG. 6. That is, in this embodiment, the selectors 410, 440 and 450 and the logical OR 460 are added to the related-art configuration. Further, as for the input/output signals, a backup data select signal NM, load data LD, a load signal LOAD, a backup data MEM are added.

The SCFF 11 performs either a normal flip-flop operation through the flip-flop 12 or a scan test operation through the flip-flop 12. Note that the normal flip-flop operation means an operation in an actual operating mode in which input logic data is held and output by the flip-flop 12. Further, the scan test operation means an operation in a scan test mode in which input scan shift data is shifted and output or an operation in which input capture data is output.

Firstly, input/output relations in the SCFF 11 are explained. A backup data select signal NM input from the scan control unit 100 is input to S-terminals of the selectors 410 and 450. A scan control signal SMC input from the scan control unit 100 is input to S-terminals of the selectors 400 and 440. An externally-input scan shift data SI is input to an A-terminal of the selector 400. Externally-input logic data DATA is input to a B-terminal of the selector 400. Load data LD input from the other SCFF 11 is input to a B-terminal of the selector 410. A LOAD signal input from the scan control unit 100 is input to the other input terminal of the logical OR 460. A clock CLK input from the scan control unit 100 is input to the one terminal of the logical OR 460 and a G-terminal of the slave latch 430.

A scan logic data SDIN output from the selector 400 is input to an A-terminal of the selector 410 and a B-terminal of the selector 450. A scan logic load data SDLIN output from the selector 410 is input to a D-terminal of the master latch 420. A master latch output LD1 output from a Q-terminal of the master latch 420 is input to a D-terminal of the slave latch 430 and an A-terminal of the selector 440. A slave latch output LD2 output from a Q-terminal of the slave latch 430 is input to an A-terminal of the selector 450 and a B-terminal of the selector 440. A master clock MCLK output from the logical OR 460 is input to a GB-terminal of the master latch 420.

A logic data Q output from the selector 450 is externally output from the SCFF 11. A backup data MEN output from the selector 440 is externally output from the SCFF 11.

Next, each component in the SCFF 11 is explained. The selector 400 (fourth selector circuit) outputs the logic data DATA or the scan shift data SI input to the SCFF 11, to the selectors 410 and 450 according to the scan control signal SMC.

That is, the selector 400 is a select circuit that makes the master latch 420 and the slave latch 430 (flip-flop 12) hold the logic data DATA or the scan shift data SI according to the scan control signal SMC. Further, the selector 400 is a select circuit that outputs the logic data DATA or the scan shift data SI from the SCFF 11 through a through-pass operation without passing the data through the master latch 420 and the slave latch 430 (flip-flop 12) according to the scan control signal SMC.

The selector 410 (second selector circuit) outputs either the data output from the selector 400, i.e., the logic data DATA or the scan shift data SI (scan logic data SDIN), or the load data LD input to the SCFF 11, to the master latch 420 according to the backup data select signal NM.

That is, the selector 410 is a select circuit that makes the master latch 420 and the slave latch 430 (flip-flop 12) hold the backup data that is input from the other SCFF 11 as the load data LD according to the backup data select signal NM. The selector 410 cooperates with the master latch 420 and thereby forms a backup input unit that receives and holds the backup data, which is the internal state of the other SCFF 11. This backup data is held at least until the scan test for the other SCFF 11 has finished. Further, the selector 410 cooperates with the slave latch 430 and thereby forms a backup input unit that receives the backup data, which is the internal state of the own SCFF 11 and has been backed up by the other SCFF 11, and restores that backup data as the internal state. This backup data is restored at least before a normal operation starts after the scan test for the SCFF 11 has finished.

The logical OR 460 calculates the logical sum of the load signal LOAD input to the SCFF 11 and the clock CLK and outputs the calculation result to the master latch 420. When the load signal LOAD is 1, a value 1 is input to the master latch 420. As a result, the master latch 420 continues holding the data. That is, the logical OR 460 is a circuit that controls the hold operation of the master latch 420 according to the load signal LOAD.

The master latch 420 temporarily holds the logic data DATA input to the SCFF 11, the scan shift data SI, or the load data LD (scan logic load data SDLIN) according to the clock CLK or the load signal LOAD (master clock MCLK) For example, the master latch 420 holds data input from D-terminal at a falling edge timing of the clock CLK input from the GB-terminal, and outputs the held data from the Q-terminal.

The slave latch 430 temporarily holds data (master latch LD1) held by the master latch 420 according to the clock CLK. For example, the slave latch 430 holds data input from the G-terminal at a rising edge timing of the clock CLK input from the G-terminal, and outputs the held data from the Q-terminal. The data held by the slave latch 430 is the internal state of the SCFF 11 (flip-flop 12). In this embodiment, in order to make it possible to perform a test while the semiconductor integrated circuit is in operation, this internal state is backed up and restored. That is, the internal state held by the slave latch 430 is backed up by the master latch 420 of the other SCFF 11. Further, the backup data backed up by the master latch 420 of the other SCFF 11 is restored into the slave latch 430 of the own SCFF 11.

The selector 440 (first selector circuit) externally outputs the logic data Q (master latch output LD1) output from the master latch 420 or the logic data Q (slave latch output LD2) output from the slave latch 430 as the backup data MEM according to the scan control signal SMC.

That is, the selector 440 functions as a backup output unit that outputs the internal state of the own SCFF held by the slave latch 430 or the internal state of the other SCFF held by the master latch 420 to the other SCFF according to the scan control signal SMC. The backup data MEM that is the internal state of the own SCFF 11 held by the slave latch 430 is output at least before the scan test for the SCFF 11 is started. Further, the backup data MEM that is the internal state of the other SCFF 11 held by the master latch 420 is output at least after the scan test for the other SCFF 11 has finished.

The selector 450 (third selector circuit) externally outputs the logic data DATA or the scan shift data SI (scan logic data SDIN) output from the selector 400, or the logic data Q (slave latch output LD2) output from the slave latch 430 as the logic data Q of the SCFF 11 according to the backup data select signal NM.

That is, the selector 450 functions as a through-pass output unit that outputs the logic data DATA or the scan shift data SI from the SCFF 11 without passing the data through the master latch 420 and the slave latch 430 (flip-flop 12) according to the backup data select signal NM. The data is output through the through-pass at least when the scan test for the other SCFF 11 is being performed, i.e., from the start of the scan test to the end of the scan test, when the SCFF 11 holds the backup data of the other SCFF 11.

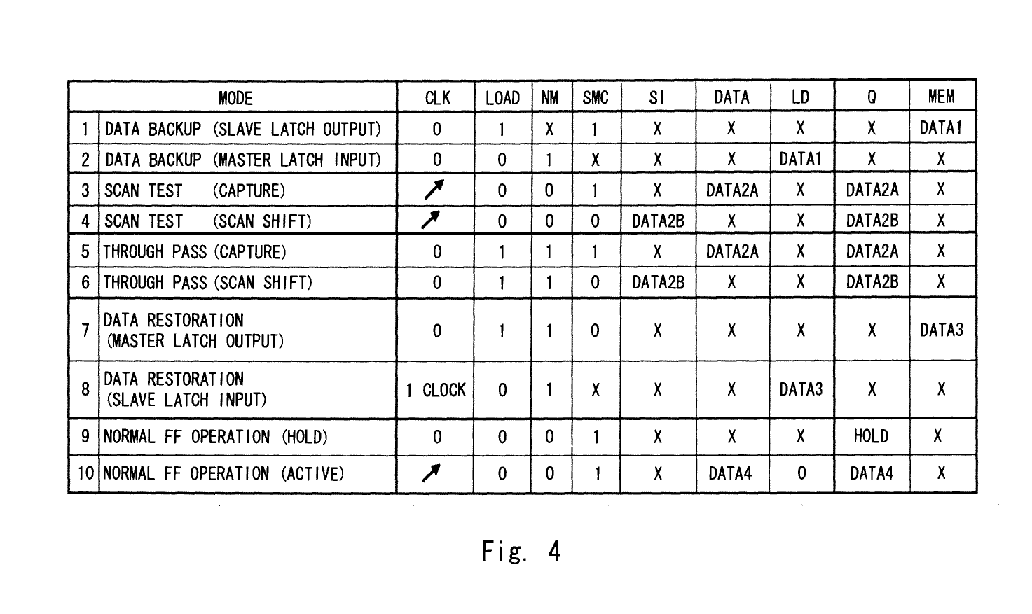

FIG. 4 is a truth table showing a relation between input and output signals and operating modes in an SCFF according to the first embodiment of the present invention. Modes 1 to 8 in FIG. 4 are the modes of the SCFF 11 in a test mode, while modes 9 and 10 are the modes of the SCFF 11 in an actual operating mode.

The SCFF 11 according to this embodiment has a data backup mode (modes 1 and 2) in which the internal state of the one SCFF backed up in the other SCFF 11, a scan test mode (modes 3 and 4 in which a scan test is performed by the one SCFF 11, a through-pass mode (modes 5 and 6) in which the other SCFF 11 performs a through-pass operation for test data of the one SCFF 11, a data restoration mode (modes 7 and 8) in which the other SCFF 11 restores the internal state backed up by the other SCFF 11 into the one SCFF 11, and a normal flip-flop (FF) operating mode which is the normal operation in an actual operating mode.

The mode 1 is a data backup mode, in particular, a slave latch output mode in which backup data DATA1 of the slave latch 430 is output from the MEM-terminal to the other SCFF 11 when the data is backed up.

In this mode, a value 0 (clock stop), a value 1, and a value 1 are input as the clock CLK, the load signal LOAD, and the scan control signal SMC respectively from the scan control unit 100 to the SCFF 11.

Since the clock CLK is 0 and the load signal LOAD is 1, the slave latch 430 holds the data. That is, the held data is not affected by the input data D. Further, since the scan control signal SMC is 1, the input B of the selector 440 is selected. Therefore, the Q-output of the slave latch 430 passes through the selector 440 and is externally output from the MEM-terminal as DATA1. In this manner, in the mode 1, the backup data that is the internal state of the slave latch 430 is output to back up the backup data in the other SCFF 11.

The mode 2 is a data backup mode, in particular, a master latch input mode in which backup data DATA1 is read from the LD terminal into the master latch 420 when the data is backed up.

In this mode, a value 0 (clock stop), a value 0, and a value 1 are input as the clock CLK, the load signal LOAD, and the backup data select signal NM respectively from the scan control unit 100 to the SCFF 11. Further, DATA1, which is backup data from the one SCFF 11, it input to the SCFF 11.

Since the clock CLK is 0 and the load signal LOAD is 0, the master latch 420 can read data. Further, since the backup data select signal NM is I, the input B of the selector 410 is selected. Therefore, DATA1 input from the LD-terminal passes through the selector 410 and is read into the master latch 420. In this manner, in the mode 2, the backup data output from the other SCFF 11 is held and backed up by the master latch 420.

The mode 3 is a scan test mode, in particular, a capture mode in which a capture operation is performed in a scan test.

In this mode, an operating clock, a value 0, a value 0, and a value 1 are input as the clock CLK, the load signal LOAD, the backup data select signal NM, and the scan control signal SMC respectively from the scan control unit 100. Further, capture data DATA2A is input from an external circuit to the DATA-terminal.

Since the clock CLK is in a clock operation state and the load signal LOAD is 0, the master latch 420 and the slave latch 430 function as a flip-flop. That is, they latch data D according to the clock CLK. Further, since the backup data select signal NM 0, the A-input of the selector 410 and the A-input of the selector 450 are selected. Further, since the scan control signal SMC is 1, the B-input of the selector 400 is selected. As a result, the data DATA2A is input from the DATA-terminal of the SCFF 11 and passes through the selectors 400 and 410. Further, the data is transferred from the D-input of the master latch 420 to the Q-output by the clock operation of the clock CLK and transferred from the D-input of the slave latch 430 to the Q-output. Finally, the data passes through the selector 450 and is externally output from the Q-terminal of the SCFF 11 as DATA2. In this manner, in the mode 3, capture data that is input in a scan test is captured and output according to the clock CLK.

The mode 4 is a scan test mode, in particular, a scan shift mode in which a scan shift operation is performed in a scan test.

In this mode, an operating clock, a value 0, a value 0, and a value 0 are input as the clock CLK, the load signal LOAD, the backup data select signal NM, and the scan control signal SMC respectively from the scan control unit 100. Further, scan shift data DATA2B is input from an external circuit to the SI-terminal.

Since the clock CLK is in a clock operation state and the load signal LOAD is 0, the master latch 420 and the slave latch 430 function as a flip-flop. Further, since the backup data select signal NM is 0, the A-input of the selector 410 and the A-input of the selector 450 are selected. Further, since the scan control signal SMC is 0, the A-input of the selector 400 is selected. As a result, the data DATA2B is input from the SI-terminal of the SCFF 11 and passes through the selectors 400 and 410. Further, the data is transferred from the D-input of the master latch 420 to the Q-output by the clock operation of the clock CLK and transferred from the D-input of the slave latch 430 to the Q-output. Final the data passes through the selector 450 and is externally output from the Q-terminal of the SCFF 11 as DATA2B. In this manner, in the mode 4, a scan shift data is input in a scan test is shifted and output according to the clock CLK.

The mode 5 is a through-pass mode, in particular, a capture through-pass mode in which a through-pass operation is performed when data is captured in a scan test.

In this mode, a value 0 (clock stop), a value 1, a value 1, and a value 1 are input as the clock CLK, the load signal LOAD, the backup data select signal NM, and the scan control sign al SMC respectively from the scan control unit 100. Further, capture data DATA2A is input to the DATA-terminal from the SCFF 11 that is performing a scan test.

Since the clock CLK is 0 and the load signal LOAD is 1, the master latch 420 and the slave latch 430 hold the data. That is, the held data is not effected by the input data D. Further, since the backup data select signal NM is 1, the input B of the selector 410 is selected. Further, since the scan control signal SMC is 1, the B-input of the selector 400 is selected. As a result, the data DATA2A is input from the DATA-terminal of the SCFF 11 and passes through the selector 450 while bypassing the master latch 420 and the slave latch 430. Then, the DATA2A is externally output from the Q-terminal of the SCFF 11. In this manner, in the mode 5, capture data that is output by the other SCFF 11 in a scan test is output by a through-pass without passing the data through the flip-flop in the own SCFF 11.

The mode 6 is a through-pass mode, in particular, a scan shift through-pass mode in which a through-pass operation is performed when scan shift is performed in a scan test.

In this mode, a value 0 (clock stop), a value 1, a value 1, and a value 0 are input as the clock CLK, the load signal LOAD, the backup data select signal NM, and the scan control signal SMC respectively from the scan control unit 100. Further, scan shift data DATA2B is input to the SI-terminal from the SCFF 11 that is performing a scan test.

Since the clock CLK is 0 and the load signal LOAD is 1, the master latch 420 and the slave latch 430 hold the data. Further, since the backup data select signal NM is 1, the input B of the selector 450 is selected. Further, since the scan control signal SMC is 0, the A-input of the selector 400 is selected. As a result, the data DATA2B is input from the SI-terminal of the SCFF 11 and passes through the selector 400 and the selector 450 while bypassing the master latch 420 and the slave latch 430. Then, the data DATA2B is externally output from the Q-terminal of the SCFF 11. In this manner, in the mode 6, scan shift data that is output by the other SCFF 11 in a scan test Is output by a through-pass without passing the data through the flip-flop in the own SCFF 11.

The mode 7 is a data restoration mode, in particular, a master latch output mode in which backup data held by the master latch 420 is output from the MEM-terminal to the other SCFF 11 when data is restored.

In this mode, a value 0 (clock stop), a value 1, a value 1, and a value 0 are input as the clock CLK, the load signal LOAD, the backup data select signal NM, and the scan control signal SMC respectively from the scan control unit 100 to the SCFF 11.

Since the clock CLE is 0 and the load signal LOAD is 1, the master latch 420 holds the data. That is, the held data is not affected by the input data D. Further, since the scan control signal SMC is 0, the input A of the selector 440 is selected. Therefore, data held by the master latch 420 is output from the Q-output, passes through the selector 440, and is externally output from the MEM-terminal as DATA3. In this manner, in the mode 7, the internal state of the other SCFF 11 that has been backed up by the master latch 420 is output to restore the internal state into the other SCFF 11.

The mode 8 is a data restoration mode, in particular, a slave latch input mode in which backup data DATA 3 is read from the LD-terminal into the master latch 420 when data is restored.

In this mode, one clock starting from 0-level is input as the clock CLK from the scan control unit 100 to the SCFF 11. Further, a value 0 and a value 1 are input as the load signal LOAD and the backup data select signal NM respectively from the scan control unit 100 to the SCFF 11. Further, DATA3 that is backup data is input from the one SCFF 11.

Firstly, since the clock CLK is 0 and the load signal LOAD is 0, the master latch 420 can read data. Since the backup data select signal NM is 1, the B-input of the selector 410 is selected. Therefore, the data DATA3 from the LD-terminal passes through the selector 410 and is read into the master latch 420.

After that, the clock OLE operates one clock. Since the load signal LOAD is 0, the master latch 420 and the slave latch 430 function as a flip-flop and the data DATA3 is read from the master latch 420 into the slave latch 430. In this manner, in the mode 8, backup data that has been backed up by the other SCFF 11 is held by the slave latch 430 and restored as the internal state of the own SCFF 11.

The mode 9 is a normal FF operating mode, in particular, a hold mode in which data of the slave latch 430 continues to be held in a normal operation.

In this mode, a value 0 (clock stop), a value 0, a value 1, and a value 0 are input as the clock CLK, the load signal LOAD, the backup data select signal NM, and the scan control signal SMC respectively from the scan control unit 100 to the SCFF 11.

Since the clock CLK is 0 and the load signal LOAD is 0, the master latch 420 can read data. Further, since the backup data select signal NM is 0, the A-input of the selector 410 is selected. Further, since the scan control signal SMC is 1, the B-input of the selector 400 is selected. However, since the clock CLK is 0, the slave latch 430 holds data and the held data is output from the Q-terminal of the SCFF 11.

In this manner, in the mode 9, the slave latch 430 continues hold data and the held data is output irrespective of the input data.

The mode 10 is a normal FF operating mode, in particular, an active mode in which input data is held and output by the flip-flop in a normal operation.

In this mode, an operating clock, a value 0, a value 0, and a value 1 are input as the clock CLK, the load signal LOAD, the backup data select signal NM, and the scan control signal SMC respectively from the scan control unit 100. Further, normal data DATA4 is input from an external circuit to the DATA-terminal.

Since the clock CLK is in a clock operation state and the load signal LOAD is 0, the master latch 420 and the slave latch 430 function as a flip-flop. That is, they latch data D according to the clock CLK. Further, since the backup data select signal NM is 0, the A-input of the selector 410 and the A-input of the selector 450 are selected. Further, since the scan control signal SMC is 1, the B-input of the selector 400 is selected. As a result, the data DATA4 is input from the DATA-terminal of the SCFF 11 and passes through the selectors 400 and 410. Further, the data is transferred from the D-input of the master latch 420 to the Q-output by the clock operation of the clock CLK and is transferred from the D-input of the slave latch 430 to the Q-output. Finally, the data passes through the selector 450 and is externally output from the Q-terminal of the SCFF 11 as DATA4. in this manner, in the mode 10, normal data that is input in a normal operation is output according to the clock CLK.

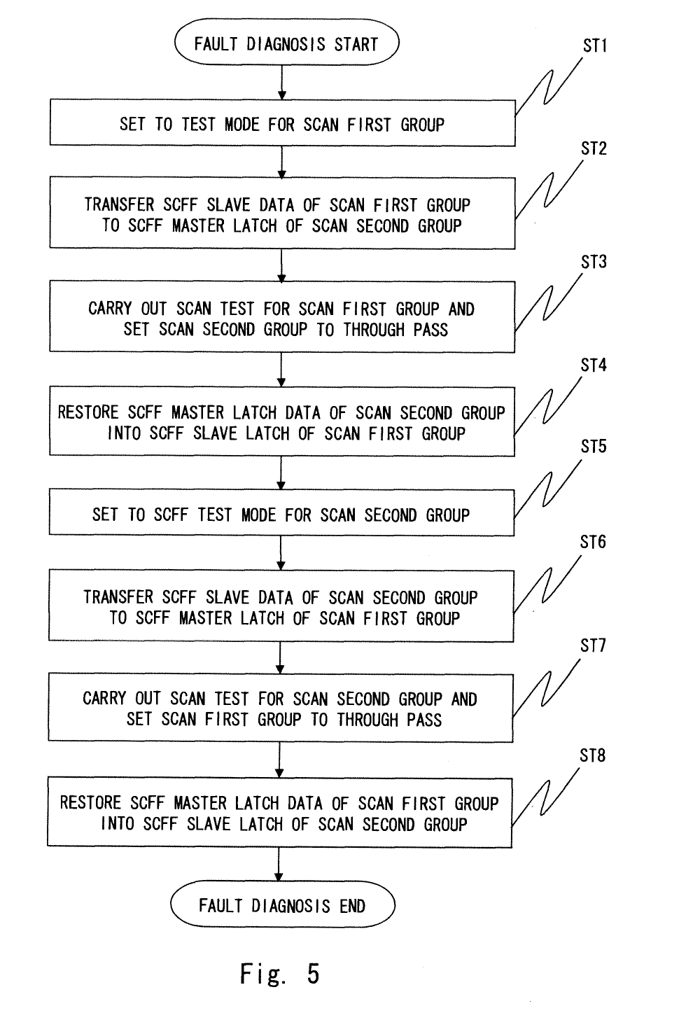

Next, a fault diagnosis operation of the semiconductor integrated circuit according to the first embodiment of the present invention is explained with reference to FIGS. 5 and 6.

FIG. 5 is a flowchart showing a fault diagnosis operation according to the first embodiment of the present invention. In this fault diagnosis operation, firstly, a scan test for the scan first group is carried out (steps ST1 to ST4) and then a scan test for the scan second group is carried out (steps ST5 to ST8). Alternatively, the scan test for the scan second group may be carried out before the scan test for the scan first group is carried out.

Firstly, when a fault diagnosis of the semiconductor integrated circuit 10 starts, the operating mode is set to a test mode for the scan first group 200 in a step ST1. That is, at the start of the fault diagnosis, mode signals MD1=1 and MD2=0 are externally input to the scan control unit 100 and the operating mode is thereby to a test mode for the scan first group. As a result, the scan control unit 100 selects the scan first group 200 as the scan group to be scan-tested and selects the scan second group 300 as the scan group in which the backup of the scan test is performed.

Next, in a step ST2, the slave data of the SCFF 210 of the scan first group 200 is transferred to the master latch of the SCFF 310 of the scan second group 300. That is, the scan control unit 100 sets the SCFF 210 of the scan first group 200 to a slave latch output mode (mode 1 in FIG. 4) sets the SCFF 310 of the scan second group 300 as a master latch input mode (mode 2 in FIG. 4).

As a result, the data (internal state) stored in the slave latch 430 of the SCFF 210 located in the scan first group 200 is temporarily stored in the master latch 420 of the SCFF 310 located in the scan second group 300 that corresponds to the SCFF 210 of the scan first group 200, and therefore the data is backed up.

Next, in a step ST3, a scan test for the scan first group 200 is carried out and the scan second group 300 is set to a through-pass That is, the scan control unit 100 sets the SCFF 210 of the scan first group 200 to a capture mode (mode 3 in FIG. 4) and a scan shift mode (mode 4 in FIG. 4) and sets the SCFF 310 of the scan second group 300 a capture through-pass mode (mode 5 in FIG. 4) and a scan shift through-pass mode (mode 6 in FIG. 4).

As a result, a scan test is carried out for the SCFF 210 located in the scan first group 200 under a predetermined scan condition. At the same time, the SCFF 310 located in the scan second group 300 performs such an operation that data just passes through the SLIT 310 by bypassing the flip-flop. In this way, a fault diagnosis is carried out for the scan first group 200.

For example, the scan test is carried out through a scan-in operation, a capture operation, and a scan-out operation. In the scan-in operation, scan shift data, i.e., test data is shifted by the SCFF 210 operating in a scan shift mode, and the shifted data is output from the SCFF 310 operating in a scan shift through-pass mode. In the capture operation, the logic circuit is operated in a state in which the scan-in operation has been already performed. Logic data of the logic circuit is taken into the SCFF 210 operating in a capture mode and the taken data is output from the SCFF 310 operating in a capture through-pass mode. In the scan-out operation, the data that has been taken into the SCFF by the capture operation is shifted by the SCFF 210 operating in a scan shift mode and the shifted data is output from the SCFF 310 operating in a scan shift through-pass mode. The data obtained by the scan-out operation is compared with expected values for the data of the scan-in operation, and the presence/absence of a fault(s) is thereby determined.

Next, in a step ST4, the data of the master latch 420 of the SCFF 310 of the scan second group 300 is restored into the slave latch 430 of the SCFF 210 the scan first group 200. That is, the scan control unit 100 sets the SCFF 310 of the scan second group 300 to a master latch output mode (mode 7 FIG. 4) and sets the SCFF 210 of the scan first group 200 to a slave latch input mode (mode 8 in FIG. 4).

As a result, the data that has been temporarily stored in the master latch 420 of the SCFF 310 of the scan second group 300 in the step ST2 is restored into the slave latch 930 of the SCFF 210 located in the scan first group 200, and the state of the SCFF 210 of the scan first group 200 is thereby restored to the pre-fault-diagnosis state. With this process, the test for the scan first group 200 has finished.

Next, in a step ST5, the operating mode is set to a test mode for the scan second group 300. That is, after the test for the scan first group has finished, order to carry out a test for the scan second group, mode signals MD1=0 and MD2=1 are externally input to the scan control unit 100 and the operating mode is thereby set to a test mode for the scan second group. As a result, the scan control unit 100 selects the scan second group 300 as the scan group to be scan-tested and selects the scan first group 200 as the scan group in which the backup the scan test is performed.

Next, in a step ST6, the slave data of the SCFF 310 of the scan second group 300 is transferred to the master latch of the SCFF 210 of the scan first group 200. That is, the scan control unit 100 sets the SCFF 310 of the scan second group 300 to a slave latch output mode (mode 1 in FIG. 4) and sets the SCFF 210 of the scan first group 200 as a master latch input mode (mode 2 in FIG. 4).

As a result, the data (internal state) stored in the slave latch 430 of the SCFF 310 located in the scan second group 300 is temporarily stored in the master latch 420 of the SCFF 210 located in the scan first group 200 that corresponds to the SCFF 310 of the scan second group 300, and therefore the data is backed up.

Next, in a step ST7, a scan test for the scan second group 300 is carried out and the scan first group 200 is set to a through-pass. That is, the scan control unit 100 sets the SCFF 310 of the scan second group 300 to a capture mode (mode 3 in FIG. 4) and a scan shift mode (mode 4 in FIG. 4) and sets the SCFF 210 of the scan first group 200 to a capture through-pass mode (mode 5 in FIG. 4) and a scan shift through-pass mode (mode 6 in FIG. 4).

As a result, a scan test is carried out for the SCFF 310 located in the scan second group 300 under a predetermined scan condition. At the same time, the SCFF 210 located in the scan first group 200 performs a through-pass operation for the data. In this way, a fault diagnosis is carried out for the scan second group 300.

Next, in a step ST8, the data of the master latch 420 of the SCFF 210 of the scan first group 200 is restored into the slave latch 430 of the SCFF 310 of the scan second group 300. That is, the scan control unit 100 sets the SCFF 210 of the scan first group 200 to a master latch output mode (mode 7 in FIG. 4) and sets the SCFF 310 of the scan second group 300 to a slave latch input mode (mode 8 in FIG. 4).

As a result, the data that has been temporarily stored in the master latch 400 of the SCFF 210 of the scan first group 200 in the step ST6 is restored into the slave latch 430 of the SCFF 310 located in the scan second group 300, the state of the SCFF 310 of the scan second group 300 is thereby restored to the pre-fault-diagnosis state.

With this process, the test for the scan first group 200 has finished and the test for the semiconductor integrated circuit 10 has been completed. At this point, since the internal state of all the SCFFs of the scan first group 200 and the scan second group 300 have been restored to the pre-test state, the normal operation can be immediately started. Therefore, even when the system including the semiconductor integrated circuit is in operation, the test can be carried out in safety.

FIG. 6 is a timing chart showing a fault diagnosis operation the semiconductor integrated circuit according to first embodiment of the present invention. In FIG. 6, the operation in the steps ST2 to ST4 in FIG. 5, which is the scan test operation for the scan first group, is shown.

In FIG. 6, a state 1 is a state in which data is backed up from the SCFF 210 of the scan first group 200 to the SCFF 310 of the scan second group 300, and corresponds to the step ST2 in FIG. 5. A state 2 is a state in which the scan test operation for the SCFF 210 of the scan first group 200 and the through-pass operation of the SCFF 310 of the scan second group 300 are performed, and corresponds to the step ST3 in FIG. 5. A state 3 is a state in which data is restored from SCFF 310 of the scan second group 300 into the SCFF 210 of the scan first group 200, and corresponds to the step ST4 in FIG. 5.

In the states 1 to 3, an operating clock signal, a value 1, and a value 0 are input as the SYSCLK, the mode signal MD1, and the mode signal MD2 respectively to the scan control unit 100. Therefore, the operating mode of the semiconductor integrated circuit 10 becomes a test mode for the scan first group.

Firstly, in the state 1 in which data is backed up from the scan first group 200 to the scan second group 300, the scan control unit 100 sets the SCFF 210 of the scan first group 200 to a slave latch output mode (mode 1 in FIG. 4) and sets the SCFF 310 of the scan second group 300 to a master latch input mode (mode 2 in FIG. 4).

That is, in the SCFF 210 of the scan first group 200, since the scan first group clock CLK1 is 0 and the scan first group load signal LOAD1 is 1, the data of the slave latch 430 is held. Further, since the scan first group scan control signal SMC1 is 1, the logic data (DATA1) the slave latch 430 of the SCFF 310 of the scan first group 200 is output from the MEM-terminal (mode 1 in FIG. 4).

Further, in the SCFF 310 of the scan second group 300, since the scan second group clock CLK2 is 0 and the scan second group load signal LOAD2 is 0, the master latch 420 can read data. Further, since the scan second group backup data select signal NM2 is 1, the logic data (DATA1) output from the MEM-terminal of the scan first group 200 is transferred from the terminal of the scan second group 300 to the master latch 420 of the SCFF 310 of the scan second group 300 and stored in that master latch 420 (mode 2 in FIG. 4).

Next, in the state 2 in which the scan test operation of the scan first group 200 and the through-pass operation of the scan second group 300 are performed, the scan control unit 100 sets the SCFF 210 of the scan first group 200 to a capture mode (mode 3 in FIG. 4) and a scan shift mode (mode 4 in FIG. 4), and sets the SCFF 310 of the scan second group 300 to a capture through-pass mode (mode in FIG. 4) and a scan shift through-pass mode (mode 6 in FIG. 4). An operation in the scan shift mode is explained hereinafter.

That is, in the SCFF 210 of the scan first group 200, the scan first group scan control signal SMC1 becomes 0 and the scan first group backup data select signal NM1 becomes 0. Further, the scan first group load signal LOAD1 becomes 0. Therefore, when the supply of the same number of clocks as the number of the SCFFs from the scan first group clock CLK1 starts, the SCFF 210 of the scan first group 200 starts a scan shift operation and logic data (DATA2) is thereby shifted from the S11 of the SCFF 210 of the scan first group 200 to the Q11 (mode 4 in FIG. 4).

Further, in the SCFF 310 of the scan second group 300, the scan second group scan control signal SMC2 is 0 and the scan second group backup data select signal NM2 is 1. Further, the scan second group load signal LOAD2 is 1 and the scan second group clock CLK2 is 0. Therefore, the scan shift data DATA2 output from the Q11 of the scan first group is input from the S21 of the scan second group, proceeds while bypassing the master latch 420 and the slave latch 430, and is externally output from the Q21 as logic data (DATA2) (mode 6 in FIG. 4). At this point, the DATA1, which is the data of the scan first group 200 and was held in the state 1, is held in the master latch 420, and the data of the scan second group 300 is still held in the slave latch 430.

Note that in the capture mode, in the SCFF 210 of the scan first group, the scan first group scan control signal SMC1 becomes 1, and logic data is captured from the D11 to the Q11 (mode 3 in FIG. 4) Further, in the SCFF 310 of the scan second group, the scan second group scan control signal SMC2 becomes 1, and logic data is output from the D21 to the Q21 by a through-pass (mode 5 in FIG. 4)

Next, in the state 3 in which data is restored from the scan second group 300 into the scan first group 200, the scan control unit 100 sets the SCFF 210 of the scan first group 200 to a slave latch input mode (mode 8 in FIG. 4) and sets the SCFF 310 of the scan second group 300 to a master latch output mode (mode 7 in FIG. 4).

That is, in the SCFF 310 of the scan second group 300, since the scan second group clock CLK2 is 0 and the scan second group load signal LOAD2 is 1, the data of the master latch 420 is held. Further, since the scan second group scan control signal SMC2 is 0, the logic data (DATA1) of the master latch 420 of the scan second group 300 is output from the MEM-terminal of the scan second group 300 (mode 7 in FIG. 4).

Further, in the SCFF 210 of the scan first group 200, since the scan first group clock CLK1 is 0 and the scan first group load signal LOAD1 is 0, the master latch 420 can read data. Further, since the scan first group backup data select signal NM1 is 1, the logic data (DATA1) output from the scan second group 300 is transferred from the LD1-terminal to the master latch 420 of the 210 of the scan first group 200. Further, when one clock is input as the scan first group clock CLK1, the logic data (DATA1) is transferred from the master latch 420 of the scan first group 200 to the slave latch 430 and stored in that slave latch 430 (mode 8 in FIG. 4).

Note that although a scan test operation for the scan first group is explained in the above explanation, a scan test operation for the scan second group can be also performed in the same manner by changing the operating mode and interchanging the operations of the scan first group and the scan second group in the above explanation.

As explained above, in this embodiment, data of the flip-flop of the scan first group to be tested is temporarily backed up in the master latch of the flip-flop of the scan second group before the test. Then, at the end of the test, the data is temporarily restored from the master latch of the flip-flop of the scan second group into the flip-flop of the scan first group. Therefore, since the internal state of the flip-flop is backed up and restored, the internal state is not destroyed. Therefore, it is possible to carry out a fault diagnosis while the semiconductor integrated circuit is in operation. Further, since the SCFF including the flip-flop serves as a storage circuit that holds the internal state, it is possible to prevent the circuit from being increased in circuit scale.

The latched data of the slave latch, which is the internal state of the flip-flop, is held by the master latch of the other flip-flop. By baking up the internal state in the master latch that has no or small effect on the internal state of the flip-flop, it is possible to use the existing circuit with efficiency. Further, when data is backed up, a through-pass operation in which data does riot pass through the flip-flop is performed. Therefore, it is possible to prevent data held in the master latch and the slave latch of the flip-flop from being updated. In this way, it is possible to prevent the internal state from being destroyed due to the implementation of a scan test and thereby to reliably restore the internal state after the scan test.

In the related-art, if all the SCFFs need to be backed up, the same number of storage devices and restoration circuits, each of which has a function of backing up data, as the number of the SCFFs are required. Therefore, the circuit increases in circuit scale by an amount equivalent to the same type of SCFFs. In the present invention, each of the exiting SCFFs serves as both a function of performing a scan test and a function of baking up data. Therefore, the circuit increases in circuit scale only by the selector circuits that control the switching between a scan test and a data backup operation.

Therefore, it is possible to reduce the circuit scale by an amount that is calculated by subtracting the circuit of the function switching selectors from the combined circuit of the same number of circuits as the total number of SCFFs and the restoration circuits. In large-scale integrated circuits, since the number of SCFFs is large, the effect obtained by using the SCFFs as storage circuits of backup data is also large.

Further, in the related-art, data backup and restoration are performed by using a control circuit. Therefore, a number of circuits for operating the control circuit are required, or timings for the control need to be created. In contrast to this, the present invention also provides anther advantageous effect that the data backup and the data restoration of SCFFs can be performed by a simple operation. That is, when data is backed up, the backup can be performed just by setting the one SCFF to a slave latch output mode and setting the other SCFF to a master latch input mode. Further, when data is restored, the restoration can be performed just by setting the one SCFF to a master latch output mode and setting the other SCFF to a slave latch input mode. Therefore, the backup and restoration can be swiftly performed with ease.

### Second Embodiment

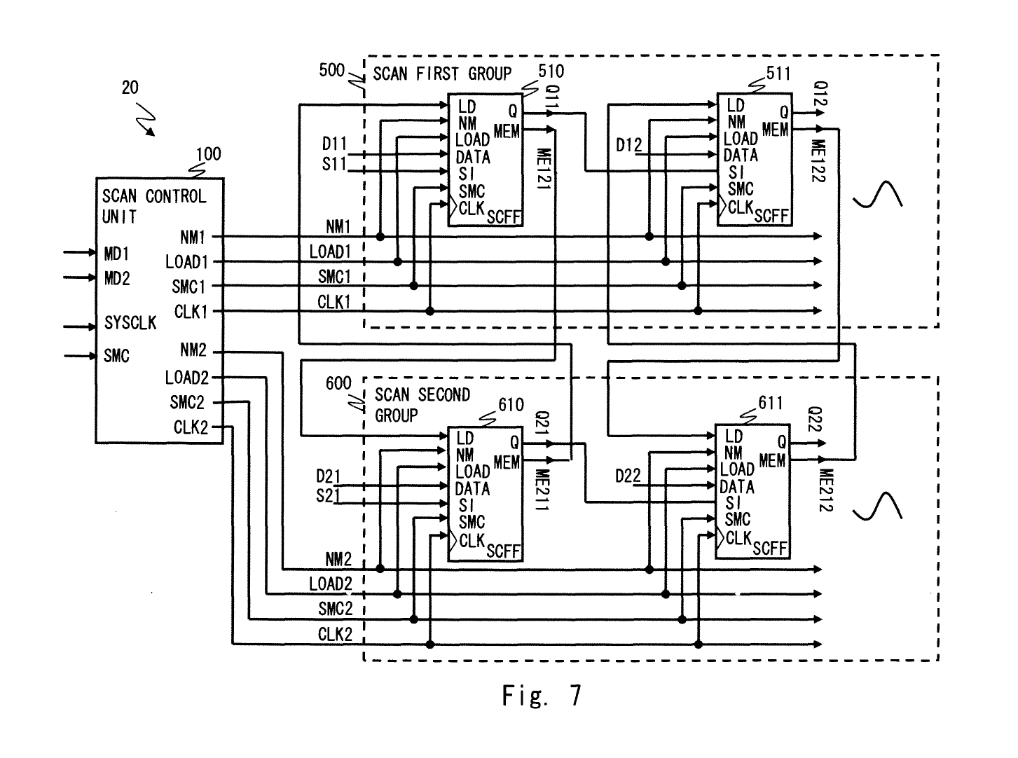

A second embodiment according to the present invention is explained hereinafter with reference to the drawings. FIG. 7 is a schematic configuration diagram of a semiconductor integrated circuit according to second embodiment of the present invention. As shown in FIG. 7, this semiconductor integrated circuit 20 includes a scan control unit 100, a scan first group 500, and a scan second group 600.

The scan first group 500 and the scan second group 600 are rent scan chains from each other, and the scan groups of this embodiment are divided into a plurality of groups according to the scan chain. Since they are divided according to the scan chain, a test is collectively carried out for each scan group.

The scan first group 500 includes a plurality of SCFFs including an SCFF 510 and an SCFF 511. Further, the scan second group 600 includes a plurality of SCFFs including an SCFF 610 and an SCFF 611. The scan chain of the scan first group 500 includes the same number of SCFFs as that of the scan chain of the scan second group 600. Examples of a system in which the scan chain of the scan first group 500 corresponds to the scan chain of the scan second soup 600 includes a system including a scan chain for testing the main processing circuit of the system and a scan chain for testing a backup processing circuit. In this example, between the two scan chains, SCFFs positioned in the same order correspond to each other. That, is, the SCFF 510 corresponds to the SCFF 610 and the SCFF 511 corresponds to the SCFF 611. Note that SCFFs positioned in the same order do not necessarily have to correspond to each other. That is, the only requirement is that SCFFs in one scan chain should correspond to SCFFs in the other scan chain in a one-to-one relation.

The scan first group backup data select signal NM1 is output from the NM1-terminla of the scan control unit 100 and input to NM-terminals of the SCFF 510, the SCFF 511, and the other SCFFs of the scan first group 500. The scan first group load signal LOAD1 is output from the LOAD1-terminla of the scan control unit 100 and input, to LOAD-terminals of the SCFF 510, the SCFF 511, and the other SCFFs of the scan first group 500. The scan first group scan control signal SMC1 is output from the SMC1-terminla of the scan control unit 100 and input to SMC-terminals of the SCFF 510, the SCFF 511, and the other SCFFs of the scan first group 500. The scan first group clock CLK1 is output from the CLK1-terminla of the scan control unit 100 and input to OLE-terminals of the SCFF 510, the SCFF 511, and the other SCFFs of the scan first group 500.

External logic data D11 for the scan first group 500 is input to a D-terminal of the SCFF 510, and external logic data D12 for the scan first group 500 is input to a DATA-terminal of the SCFF 511. External scan shift data S11 for the scan first group 500 is input to an SI-terminal of the SCFF 510, and logic data Q11 output from a Q-terminal of the SCFF 510 in the scan first group 500 is input to an SI-terminal of the SCFF 511. Logic data Q12 output from a Q-terminal of the SCFF 511 in the scan first group 500 is input to an SI-terminal of another SCFF adjacent to the SCFF 511. Scan first group backup data ME121 output from an MEM-terminal of the SCFF 510 of the scan first group 500 is input to an LD-terminal of the SCFF 610 of the scan second group 600. Scan first group backup data ME122 output from an MEM-terminal of the SCFF 511 of the scan first group 500 is input to an LD-terminal of the SCFF 611 of the scan second group 600.

The scan second group backup data select signal NM2 is output from the NM2-terminla of the scan control unit 100 and input to NM-terminals of the SCFF 610, the SCFF 611, and the other SCFFs of the scan second group 600. The scan second group load signal LOAD2 is output from the LOAD2-terminla of the scan control unit 100 and input to LOAD-terminals of the SCFF 610, the SCFF 611, and the other SCFFs of the scan second group 600. The scan second group scan control signal SMC2 is output from the SMC2-terminla of the scan control unit 100 and input to SMC-terminals of the SCFF 610, the SCFF 611, and the other SCFFs of the scan second group 600. The scan second group clock CLK2 is output from the CLK2-terminla of the scan control unit 100 and input to CLK-terminals of the SCFF 610, the SCFF 611, and the other SCFFs of the scan second group 600.

External logic data 921 for the scan second group 600 is input to a D-terminal of the SCFF 610, and external logic data 922 for the scan second group 600 is input to a DATA-terminal of the SCFF 611 External scan shift data S21 for the scan second group 600 is input to an SI-terminal of the SCFF 610. Logic data Q21 output from a Q-terminal of the SCFF 610 in the scan second group 600 is input to an SI-terminal of the SCFF 611. Logic data Q22 output from a terminal of the SCFF 611 the scan second group 600 is input to an SI-terminal of the SCFF adjacent to the SCFF 611. Backup data ME211 output from an MEM-terminal of the SCFF 610 of the scan second group 600 is input to an terminal of the SCFF 510 of the scan first group 500. Backup data ME212 output from an MEM-terminal of the SCFF 611 of the scan second group 600 is input to an LD-terminal of the SCFF 511 of the scan first group 500.

The scan chain of the scan first group 500 has such a configuration that an external S11 signal is input to the SI-terminal of the SCFF 510: the signal is input from the Q-terminal of the SCFF 510 to the SI-terminal of the SCFF 511; and the data is shifted to the Q-terminal the SCFF 511 and to another SCFF of the scan first group.

The scan chain of the scan second group 600 has such a configuration that an external S21 signal is input to the SI-terminal of the SCFF 610: the signal is input from the Q-terminal of the SCFF 610 to the SI-terminal of the SCFF 611; and the data is shifted to the Q-terminal of the SCFF 611 and to another SCFF of the scan second group.

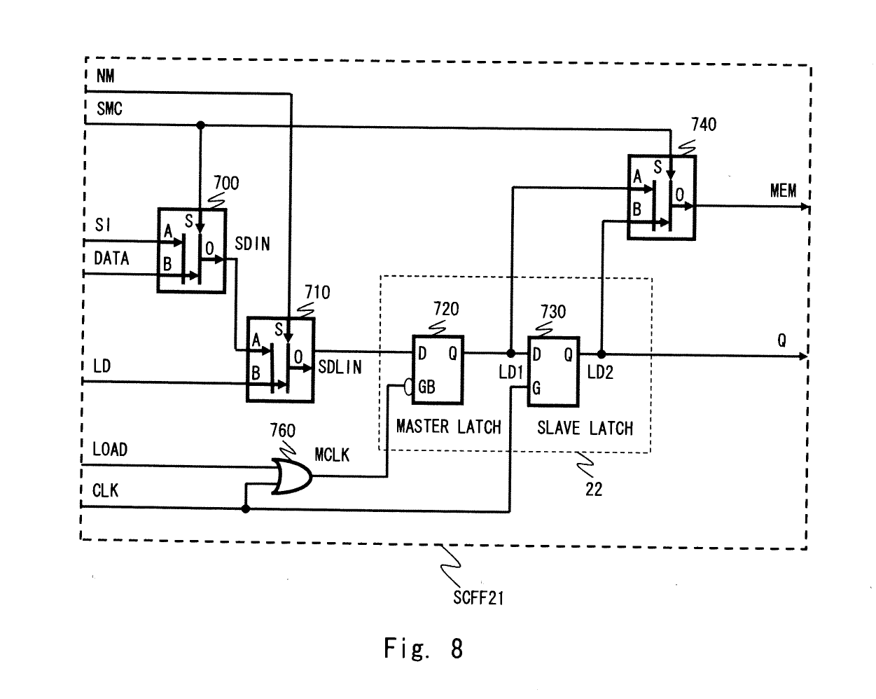

FIG. 8 is a circuit configuration diagram of an SCFF according to the second embodiment of the present invention. This SCFF 21 corresponds to the SCFFs 510 and 511 of the scan first group 500 and to the SCFFs 610 and 611 of the scan second group 600.

As shown in FIG. 7, the SCFF 21 includes selectors 700, 710 and 740, a master latch 720, a slave latch 730, and a logical OR 760. Further, the master latch 720 and the slave latch 730 form flip-flop 22.

Firstly, input/output relations in the SCFF 21 are explained. A backup data select signal NM input from the scan control unit 100 is input to an S-terminal of the selector 710. A scan control signal SMC input from the scan control unit 100 is input S-terminals of the selectors 700 and 740. An externally-input scan shift data SI is input to an A-terminal of the selector 700. An externally-input logic data DATA is input to a B-terminal of the selector 700. A load data LD input from the other SCFF 21 is input to a B-terminal of the selector 710. A LOAD signal input from the scan control unit 100 is input to the other input terminal of the logical OR 760. A clock CLK input from the scan control unit 100 is input to the one input terminal of the logical OR 760 and a G-terminal of the slave latch 730.

A scan logic data SPIN output from the selector 700 is input to an A-terminal of the selector 710. A scan logic load data SDLIN output from the selector 710 is input to a D-terminal of the master latch 720. A master latch output LD1 output from a Q-terminal of the master latch 720 is input to a D-terminal of the slave latch 730 and an A-terminal of the selector 740. A slave latch output Q (logic data Q) output from a Q-terminal of the slave latch 730 is input to a B-terminal of the selector 740 and externally output from the SCFF 21. A master clock MCLK output from the logical OR 760 is input to a GB-terminal of the master latch 720. A backup data MEM output from the selector 740 is externally output from the SCFF 21.

Next, each component in the SCFF 21 is explained. The selectors 700, 710 and 140, the master latch 720, the slave latch 730, and the logical OR 760 in FIG. 8 have similar configurations as those of the selectors 400, 410 and 440, the master latch 420, the slave latch 430, and the logical OR 460 shown in FIG. 3. The SCFF 21 shown in FIG. 8 is different from the SCFF 11 shown in FIG. 3 only in that the SCFF 21 does not include the selector 450.

That is, the selector 700 outputs the logic data DATA or the scan shift data SI input to the SCFF 21 only to the selector 710 according to the scan control signal SMC, and the logic data Q (slave latch output LD2) output from the slave latch 730 is externally output. Further, only the selector 710 is controlled by the backup data select signal NM and the scan logic load data SDLIN is output to the master latch 720.

Therefore, the SCFF 21 shown in FIG. 8 does not perform the through-pass operation in which the master latch 720 and the slave latch 730 (flip-flop 22) are bypassed, and the logic data Q is always output through the master latch 720 and the slave latch 730 (flip-flop 22).

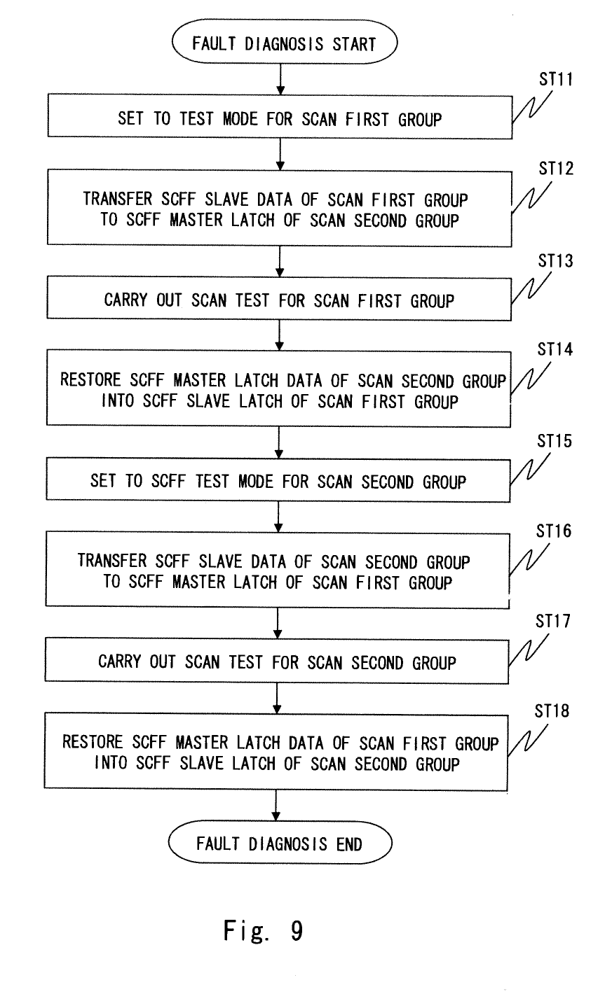

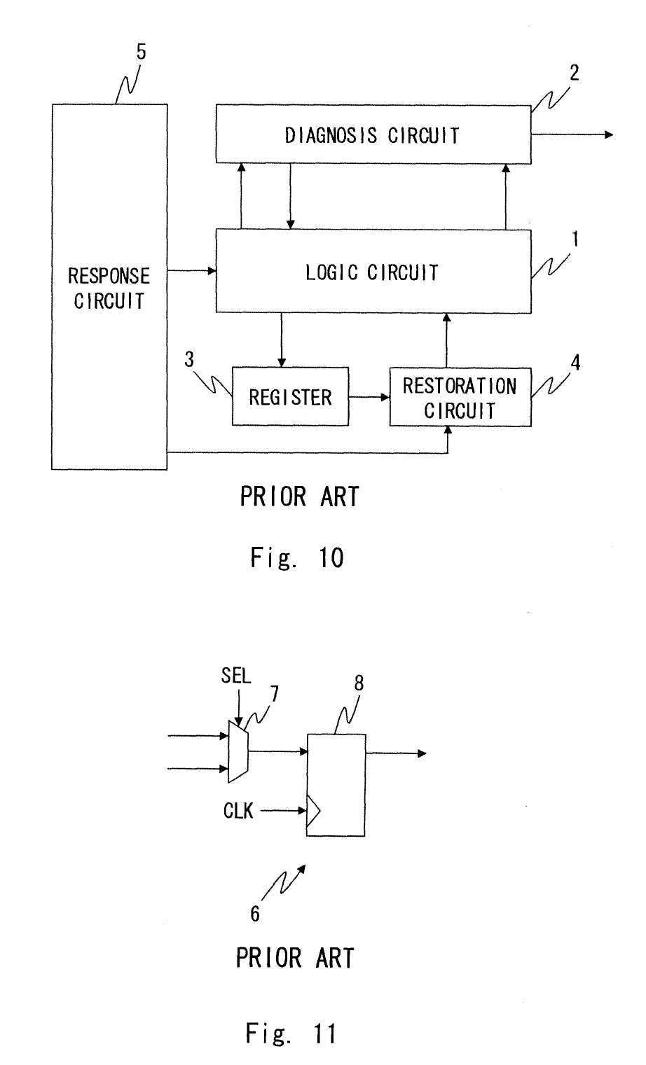

FIG. 9 is a flowchart showing a fault diagnosis operation according to the second embodiment of the present invention. Note that explanation of operations similar to those in FIG. 5 is omitted as appropriate.

Firstly, when a fault gnosis of the semiconductor Integrated circuit 20 starts, the operating mode is set to a test mode for the scan first group 500 in a step ST1.

Next, in a step ST12, the slave data of the SCFFs 510 and 511 of the scan first group 500 is transferred to the master latches of the SCFFs 610 and 611 of the scan second group 600. That is, the scan control unit 100 sets the SCFFs 510 and 511 of the scan first group 500 to a slave latch output mode (mode 1 in FIG. 4) and sets the SCFFs 610 and 611 of the scan second group 600 as master latch input mode (mode 2 FIG. 4).

As a result, in the data backup of the SCFF 510 of the scan first group 500, data stored in the slave latch 730 of the SCFF 510 located in the scan first group 500 is output from the MEM-output terminal of the SCFF 510. The output data is input from the LD-terminal of the SCFF 610 located in another adjacent scan second group 600 having a scan chain configuration and temporarily stored in the master latch 720 of the SCFF 610.

Further, in the data backup of the SCFF 511 of the scan first group 500, data stored in the slave latch 730 of the SCFF 511 located in the scan first group 500 is output from the MEM-output terminal of the SCFF 511. The output data is input from the LD-terminal of the SCFF 611 located in another adjacent scan second group 600 having a scan chain configuration and temporarily stored in the master latch 720 of the SCFF 611.

Next, in a step ST13, a scan test for the scan first group 500 is carried out. That is, the scan control unit 100 sets the SCFFs 510 and 511 of the scan first group 500 to a capture mode (mode 3 in FIG. 4) and a scan shift mode (mode 4 in FIG. 4).

As a result, a scan test is carried out for the SCFFs 510 and 511 located in the scan first group 500 under a predetermined scan condition. In this embodiment, unlike the first embodiment, the scan second group does not perform the through-pass operation when the scan test for the scan first group is carried.

The scan shift operation of the scan first group 500 is carried out on the path of the scan chain of the scan first group 500. Specifically, scan shift data, which is externally input to the S11 of the an first group 500, is input to the SI-terminal of the SCFF 510. Then, the data Q11 that is obtained by shifting the S11 is input from the Q-terminal of the SCFF 510 to the SI-terminal of the SCFF 511. Further, the data Q12 that is obtained by shifting the Q11 is output from the Q-terminal of the SCFF 511 and input to the SI-terminal of another adjacent SCFF. In this way, the SCFFs in the scan first group 500 function as a shift register and thereby shift the scan shift data. In this embodiment, the scan shift data passes only through the scan chain of the scan first group 500 and does not pass through the scan second group 600.

Next, in a step ST14, the data of the master latches 720 of the SCFFs 610 and 611 of the scan second group 600 is restored into the slave latches 730 of the SCFFs 510 and 511 of the scan first group 500. That is, the scan control unit 100 sets the SCFFs 610 and 611 of the scan second group 600 to a master latch output mode (mode 7 in. FIG. 4) and sets the SCFFs 510 and 511 of the scan first group 500 to a slave latch input mode (mode 8 in FIG. 4).

As a result, in the data restoration of the SCFF 610 of the scan second group 600, the data that has been temporarily stored in the master latch 720 of the SCFF 610 of the scan second group 600 is output from the MEM-terminal of the SCFF 610. The output data is input to the LD-terminal of the SCFF 510 located in the scan first group 500 and restored into the slave latch 730 of the SCFF 510 through the master latch 720.

Further, in the data restoration of the SCFF 611 of the scan second group 600, the data that has been temporarily stored in the master latch 720 of the SCFF 611 of the scan second group 600 is output from the MEM-terminal of the SCFF 611. The output data is input to the LD-terminal of the SCFF 511 located in the scan first group 500 and restored into the slave latch 730 of the SCFF 511 through the master latch 720. With this process, the test for the scan first group 500 has finished.

Next, in steps ST15 to ST18, a test for the scan second group is carried out in a similar manner to the steps ST11 to ST14. That is, the operating mode is set to a test mode for the scan second group 600 (ST15); slave data of the SCFFs 610 and 611 of the scan second group 600 is transferred to the master latch 720 of the SCFFs 510 and 511 of the scan first group 500 (ST16); a scan test for the scan second group 600 is carried out (ST17); and data of the master latches 720 of the SCFFs 510 and 511 of the scan first group 500 is restored into the slave latches 730 of trip SCFFs 610 and 611 of the scan second group 600 (ST18). With these processes, the test for the scan second group 600 has finished and the test for the semiconductor integrated circuit 20 has been completed.

As described above, in this embodiment, data of SCFFs of the scan first group (scan chain A) to be tested is temporarily backed up in the master latches of SCFFs of the scan second group (scan chain B). Therefore, similarly to the first embodiment, the internal state is backed up by SCFFs. As a result, in comparison to the related-art semiconductor integrated circuit, it is possible to prevent the circuit from being increased in circuit scale.

Further, since the mode can be changed for each scan chain in this embodiment, there is no need to set SCFFs to a through-pass mode. Therefore, the circuit can be reduced in circuit scale even further. There is no need to have a function of a through-pass mode (modes 5 and 6), and the selector 450, which is provided in the SCFF shown in FIG. 2, can be thereby omitted.

That is, it is possible to restore the internal state to the pre-fault-diagnosis state while simplifying the function of the SCFF and thereby reducing a number of cells and the circuit scale.

Note that the present invention is not limited to the above-described embodiments, and various modifications can be made without departing from the spirit and scope of the present invention. For example, the above-described invention may be applied to all of a plurality of SCFFs included in a semiconductor integrated circuit or may be applied only to some of the SCFFs. For example, only the internal state that is essential to the safety operation of the system may be backed up. That is, the above-described invention may be applied only to the SCFFs whose internal state needs to be backed up, so that the increase in circuit scale can be minimized.

The first and second embodiments be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor integrated circuit comprising:
first and second scan flip-flops that perform either a normal flip-flop operation through an internal flip-flop or a scan test operation through the internal flip-flop; and
a scan control unit that controls the scan test operation performed by the first and second flip-flops, wherein
the first scan flip-flop comprises a first backup output unit that outputs backup data under control of the scan control unit, the backup data being held by a first flip-flop located in the first scan flip-flop as an internal state, and
the second scan flip-flop comprises a first backup input unit that stores backup data output from the first scan flip-flop into a second flip-flop located in the second scan flip-flop under control of the scan control unit.

2. The semiconductor integrated circuit according to claim 1, wherein
the first backup output unit outputs the backup data before a scan test for the first scan flip-flop starts, and
the first backup input unit holds the backup data until the scan test for the first scan flip-flop has finished.

3. The semiconductor integrated circuit according to claim 1, wherein
the first flip-flop comprises a master latch that holds and outputs input data, and a slave latch that holds output data of the master latch, and
the backup data is data held by the slave latch.

4. The semiconductor integrated circuit according to claim 1, wherein
the second flip-flop comprises a master latch that holds and outputs input data, and a slave latch that holds output data of the master latch, and
the master latch holds the backup data.

5. The semiconductor integrated circuit according to claim 1, wherein
the second scan flip-flop comprises a second backup output unit that outputs backup data held by the second flip-flop under control of the scan control unit, and
the scan flip-flop comprises a second backup input unit that restores backup data output from the second scan flip-flop as an internal state of the first flip-flop under control of the scan control unit.

6. The semiconductor integrated circuit according to claim 5, wherein
the second backup output unit outputs the backup data after a scan test for the first scan flip-flop finishes, and
the second backup input unit restores the backup data before the first scan flip-flop starts a normal flip-flop operation.

7. The semiconductor integrated circuit according to claim 5, wherein
the second flip-flop comprises a master latch that holds and outputs input data, and a slave latch that holds output data of the master latch, and
the master latch holds the backup data.

8. The semiconductor integrated circuit according to claim 5, wherein
the first flip-flop comprises a master latch that holds and outputs input data, and a slave latch that holds output data of the master latch, and
the backup data is held by the slave latch and the internal state is thereby restored.

9. The semiconductor integrated circuit according to claim 1, wherein the second scan flip-flop comprises a through-pass output unit that outputs test data output from the first scan flip-flop by a scan test operation, by a through-pass without passing the test data through the second flip-flop under control of the scan control unit.

10. The semiconductor integrated circuit according to claim 9, wherein the through-pass output unit outputs test data by the through-pass during a period from a start of a scan test for the first scan flip-flop to an end of the scan test.

11. The semiconductor integrated circuit according to claim 9, wherein the through-pass output unit output test data by the through-pass during a period in which the second flip-flop holds the backup data.

12. The semiconductor integrated circuit according to claim 1, further comprising a plurality of first scan flip-fl and a same number of second scan flip-flops as a number of the first scan flip-flops, wherein
each of the plurality of first scan flip-flops outputs the backup data to a corresponding one of the plurality of second scan flip-flops, and
each of the plurality of second scan flip-flops holds the backup data output from a corresponding one of the plurality of first scan flip-flops.

13. The semiconductor integrated circuit according to claim 12, wherein
each of the plurality of second scan flip-flops outputs the held backup data to the corresponding one of the plurality of first scan flip-flops, and
each of the plurality of first scan flip-flops restores the backup data output from the corresponding one of the plurality of second scan flip-flops as an internal state.

14. The semiconductor integrated circuit according to claim 12, wherein
the plurality of first scan flip-flops are connected to one another and thereby forms a scan chain, and
the plurality of second scan flip-flops are connected to one another and thereby forms a scan chain different from the scan chain formed by the plurality of first scan flip-flops.

15. A scan flip-flop comprising:
a master latch that holds and outputs input data; and
a slave latch that holds and outputs data output by the master latch, wherein
the scan flip-flop further comprises:
a first selector circuit that outputs either master data held by the master latch or slave data held by the slave latch as backup data; and
a second selector circuit that supplies one of input logic data input from an external logic circuit, scan shift data to be scan-shifted, and the backup data output from another scan flip-flop to the master latch.

16. The scan flip-flop according to claim 15, wherein first selector circuit outputs the master data or the slave data according to a scan mode control signal for switching an operating mode to a normal operating mode or a scan test mode.

17. The scan flip-flop ac ding to claim 15, wherein the second selector circuit outputs the input logic data, the scan shift data, or the backup data according to a backup data select signal for selecting backup data to be output.

18. The scan flip-flop according to claim 15, further comprising a logical OR circuit that outputs a result of a logical sum of a clock signal for controlling a hold operation of the master latch and the slave latch and a load signal for controlling d hold operation of the master latch, wherein
the master latch holds output data of the second selector circuit according to output of the logical OR circuit, and
the slave latch holds output data of the master latch according to the clock signal.

19. The scan flip-flop according to claim 15, further comprising a third selector circuit that outputs one of the input logic data, the scan shift data, and the slave data as output data of the scan flip-flop.

20. The scan flip-flop according to claim 19, wherein the third selector circuit outputs one of the input logic data, the scan shift data, and the slave data according to a backup data select signal for selecting backup data to be output.

21. The scan flip-flop according to claim 15, further comprising a fourth selector circuit that outputs either the input logic data or the scan shift data to the second selector circuit according to a scan mode control signal for switching an operating mode to a normal operating mode or a scan test mode.

22. The scan flip-flop according to claim 19, further comprising a fourth selector circuit that outputs either the input logic data or the scan shift data to the second selector circuit and the third selector circuit according to a scan mode control signal for switching an operating mode to a normal operating mode or a scan test mode.

23. A test method of a semiconductor integrated circuit comprising first and second scan flip-flops that perform either a normal flip-flop operation through an internal flip-flop or a scan test operation through the internal flip-flop, wherein
the first scan flip-flop outputs backup data, the backup data being held by a first flip-flop located in the first scan flip-flop as an internal state, and
the second scan flip-flop stores backup data output from the first scan flip-flop into a second flip-flop located in the second scan flip-flop.

24. The test method of a semiconductor integrated circuit according to claim 23, wherein
the first flip-flop comprises a master latch that holds and outputs input data, and a slave latch that holds output data of the master latch, and
the backup data is data held by the slave latch.

25. The test method of a semiconductor integrated circuit according to claim 23, wherein
the second flip-flop comprises a master latch that holds and outputs input data, and a slave latch that holds output data of the master latch, and
the master latch holds the backup data.
